(19) United States
(12) Patent Application Publication
(10) Pub. No.: US 2023/0187183 A1
(43) Pub. Date: Jun. 15, 2023

(54) UPPER ELECTRODE AND PLASMA PROCESSING APPARATUS

(71) Applicant: Tokyo Electron Limited, Tokyo (JP)

(72) Inventors: Torai IWASA, Miyagi (JP); Masaya HERAI, Miyagi (JP); Takahiro SENDA, Miyagi (JP)

(73) Assignee: Tokyo Electron Limited, Tokyo (JP)

(21) Appl. No.: 18/073,185

(22) Filed: Dec. 1, 2022

(30) Foreign Application Priority Data
Dec. 13, 2021 (JP) 2021-201526

(51) Int. Cl. H01J 37/32

(52) U.S. Cl. CPC H01J 37/3255; H01J 37/32715

(57) ABSTRACT

An upper electrode disclosed configures a shower head in a capacitively-coupled plasma processing apparatus. The upper electrode includes a first member and a first member. The first member includes a conductor. The first member provides a plurality of first holes. The plurality of first holes penetrate the first member. The second member includes a main body and a cover layer. The main body includes a conductor and is provided above the first member. The cover layer covers the surface of the main body. The second member provides one or more second holes. The secondary electron emission coefficient of the cover layer is smaller than 1.

### CROSS-REFERENCE TO RELATED APPLICATIONS

This application claims priority to Japanese Patent Application No. 2021-201526, filed on Dec. 13, 2021, the entire contents of which are incorporated herein by reference.

### TECHNICAL FIELD

The present disclosure relates to an upper electrode and a plasma processing apparatus.

### BACKGROUND

In plasma processing on a substrate, a plasma processing apparatus is used. One type of plasma processing apparatus is a capacitively-coupled plasma processing apparatus and includes a plasma processing chamber, a substrate support, and an upper electrode. The substrate support is provided in the plasma processing chamber. The upper electrode is provided above the substrate support. The upper electrode configures a shower head and includes a silicon electrode plate.

### PRIOR ART DOCUMENTS

### Patent Documents

Patent Document 1: JP-A-2003-51485

### SUMMARY

The present disclosure provides a technique for suppressing an abnormal discharge in an upper electrode.

In one exemplary embodiment, an upper electrode is provided. The upper electrode configures a shower head in a capacitively-coupled plasma processing apparatus. The upper electrode includes a first member and a second member. The first member is formed of a conductor. The first member provides a plurality of first holes. The plurality of first holes penetrate the first member. The second member includes a main body and a cover layer. The main body is formed of a conductor and is provided above the first member. The cover layer covers at least a part of the surface of the main body. The second member provides one or more second holes. The secondary electron emission coefficient of the cover layer is smaller than 1.

According to one exemplary embodiment, an abnormal discharge in an upper electrode is suppressed.

### BRIEF DESCRIPTION OF THE DRAWINGS

FIG. 1 is a diagram schematically showing a plasma processing apparatus according to an exemplary embodiment.

FIG. 2 is a partially enlarged cross-sectional view of the upper electrode according to the exemplary embodiment.

FIG. 3 is a partially enlarged cross-sectional view of the upper electrode according to the exemplary embodiment.

FIG. 4 is a partially enlarged cross-sectional view of an upper electrode according to another exemplary embodiment.

FIG. 5 is a partially enlarged cross-sectional view of an upper electrode according to still another exemplary embodiment.

FIG. 6 is a partially enlarged cross-sectional view of an upper electrode according to still another exemplary embodiment.

FIG. 7 is a schematic cross-sectional view illustrating a test apparatus.

FIG. 8 is a graph illustrating test results.

### DETAILED DESCRIPTION

Hereinafter, various exemplary embodiments will be described.

In one exemplary embodiment, an upper electrode is provided. The upper electrode configures a shower head in a capacitively-coupled plasma processing apparatus. The upper electrode includes a first member and a second member. The first member is formed of a conductor. The first member provides a plurality of first holes. The plurality of first holes penetrate the first member. The second member includes a main body and a cover layer. The main body is formed of a conductor and is provided above the first member. The cover layer covers at least a part of the surface of the main body. The second member provides one or more second holes. The secondary electron emission coefficient of the cover layer is smaller than 1.

In the embodiment described above, the surface of the main body of the second member is covered with the cover layer having the secondary electron emission coefficient smaller than 1. Therefore, even when electrons or positive ions enter the plurality of first holes in the plasma processing chamber and collide with the second member, the amount of secondary electrons emitted from the second member is small. As a result, an abnormal discharge in the upper electrode is suppressed.

In one exemplary embodiment, the cover layer may be formed of a conductor. According to the embodiment, the secondary electrons are exhausted from the upper electrode to the ground through the cover layer. The secondary electrons are exhausted to the ground through, for example, the cover layer, the first member, and the plasma in the plasma processing chamber. Therefore, the potential difference between the first member and the second member is suppressed. Therefore, the abnormal discharge in the upper electrode is further suppressed.

In one exemplary embodiment, the cover layer may contain polyimide, polytetrafluoroethylene, or perfluoroalkoxy ethylene.

In another exemplary embodiment, the upper electrode is also provided. The upper electrode configures a shower head in a capacitively-coupled plasma processing apparatus. The upper electrode includes a first member and a second member. The first member is formed of a conductor. The first member provides a plurality of first holes. The plurality of first holes penetrate the first member. The second member includes a main body and a cover layer. The main body is formed of a conductor and is provided above the first member. The cover layer covers at least a part of the surface of the main body. The second member provides one or more second holes. The cover layer is a layer containing diamond-like carbon, amorphous carbon, or silicon carbide.

The secondary electron emission coefficient of diamond-like carbon, amorphous carbon, and silicon carbide is smaller than 1. Therefore, in the above-described embodiment, even when electrons or positive ions enter the plurality of first holes from the plasma in the plasma processing chamber and collide with the second member, the amount of the secondary electrons emitted from the second member is small. Further, the secondary electrons are exhausted from the upper electrode to the ground through the layer of diamond-like carbon. Therefore, the potential difference between the first member and the second member is suppressed. Therefore, the abnormal discharge in the upper electrode is suppressed.

In one exemplary embodiment, the second member may further include an insulating layer that is provided between the cover layer and the surface of the main body. In the embodiment, the main body of the second member and the first member are not in direct communication with each other.

In one exemplary embodiment, the upper electrode may further include a conductive member that is provided between the first member and the second member. The conductive member may be in contact with the first member and the cover layer. In the embodiment, the secondary electrons flow to the first member through the cover layer and the conductive member. The secondary electrons flowing to the first member are exhausted to the ground through the plasma in the plasma processing chamber. Therefore, the potential difference between the first member and the second member is suppressed. Therefore, the abnormal discharge in the upper electrode is further suppressed.

In one exemplary embodiment, the second member may provide a plurality of second holes as the one or more second holes. The plurality of second holes communicate with the plurality of first holes, respectively.

In one exemplary embodiment, the second member may include an end portion defining an opening of each of the plurality of second holes on a side of the first member. The end portion may have a tapered shape. The diameter of the opening of each of the plurality of second holes may be larger than the diameter of each of the plurality of first holes. The surface of the end portion may be formed of the cover layer. The electrons or positive ions entering the plurality of first holes may collide with the end portion of each of the plurality of second holes. In the embodiment, since the surface of the end portion of each of the plurality of second holes is formed of the cover layer, the generation of the secondary electrons in the end portion is effectively suppressed.

In one exemplary embodiment, the second member may provide a gas diffusion chamber. Each of the plurality of second holes may extend from the gas diffusion chamber toward the first hole.

In one exemplary embodiment, the second member may further provide a flow path that is provided for allowing a refrigerant to flow through the flow path.

In one exemplary embodiment, at least one of each of the plurality of first holes and each of the one or more second holes may be a gas hole.

In one exemplary embodiment, the cover layer may cover at least an entire region that faces the first member of the surface of the main body.

In one exemplary embodiment, the cover layer may cover at least the region that defines the opening of each of the second holes on a side of the first member of the surface of the main body. The region faces the first member.

In one exemplary embodiment, the cover layer may cover at least a region that faces an opening of the first hole on a side of the second member of the surface of the main body. The region is a region susceptible to the collision of electrons or positive ions entering each of the plurality of first holes from the plasma in the plasma processing chamber. In the embodiment, since the region is covered with the cover layer, the generation of secondary electrons from the region is suppressed. Therefore, the abnormal discharge in the upper electrode is further suppressed.

In still another exemplary embodiment, the plasma processing apparatus includes a plasma processing chamber, a substrate support, and an upper electrode. The plasma processing chamber provides a processing space thereinside. The substrate support is provided in the plasma processing chamber. The upper electrode is an upper electrode of any one of the various exemplary embodiments described above, and is provided above the substrate support.

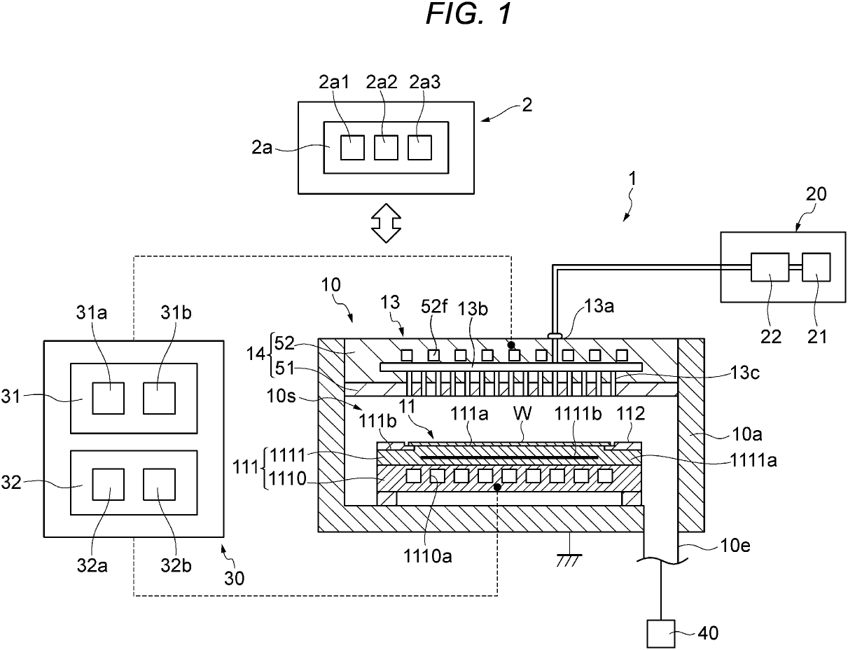

Hereinafter, an example of the configuration example of a plasma processing system will be described. FIG. 1 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body portion 111 has a central region 111a for supporting the substrate W and an annular region 111b for supporting the ring assembly 112. The wafer is an example of the substrate . The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power supply 31 and/or a direct current (DC) power supply 32 to be described later may be disposed in the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between the rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 14 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode 14. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode 14 via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode 14.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode 14 to generate a second DC signal. The generated second DC signal is applied to at least one upper electrode 14.

In various embodiments, at least one of the first and second DC signals may be pulsed. In this case, the sequence of voltage pulses is applied to at least one lower electrode and/or at least one upper electrode 14. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode 14. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

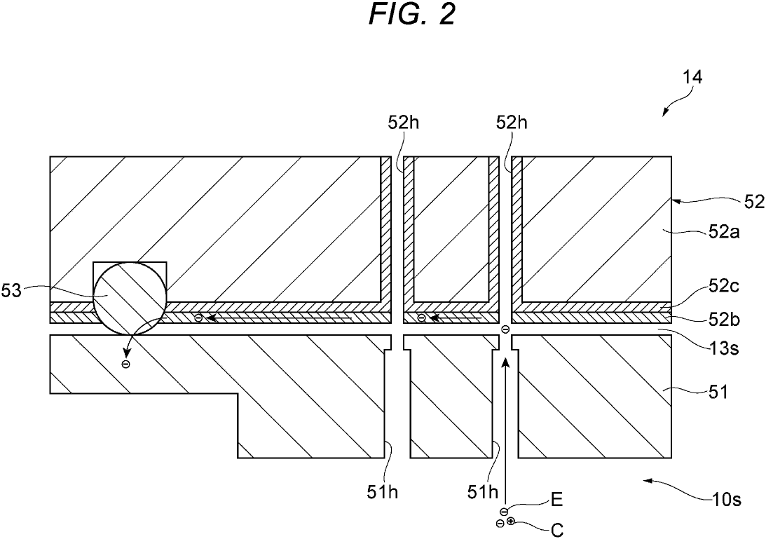

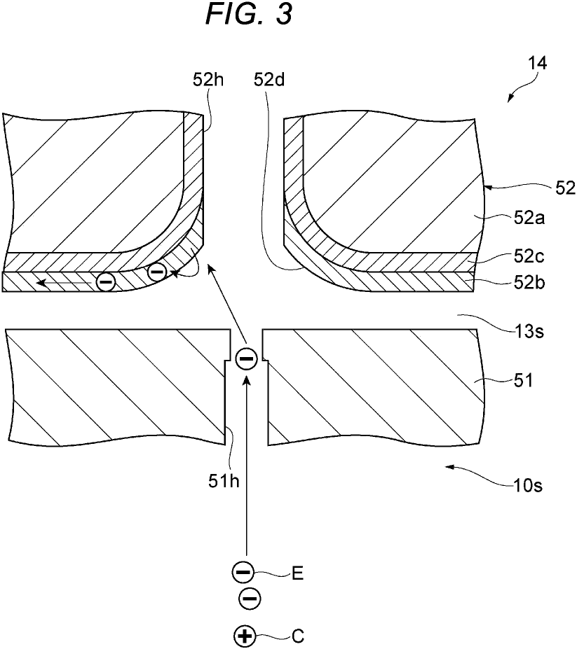

In the plasma processing apparatus 1, the upper electrode 14 configures the shower head 13. Hereinafter, the upper electrode 14 according to the exemplary embodiment will be described with reference to FIGS. 2 and 3. FIGS. 2 and 3 are partially enlarged cross-sectional views of the upper electrode 14 according to the exemplary embodiment. The upper electrode 14 may be used as the upper electrode in the plasma processing apparatus 1.

As shown in FIG. 2, the upper electrode 14 includes a first member 51 and a second member 52. The first member 51 may be a top plate that defines a space inside the plasma processing chamber 10 (the plasma processing space 10s) from above. The first member 51 may have a substantially disc shape. The first member 51 has a plurality of first holes 51h. The plurality of first holes 51h penetrate the first member 51 in a plate thickness direction thereof. The first member 51 is formed of a conductor. The first member 51 may be formed of a silicon-containing material such as silicon or silicon carbide.

As shown in FIG. 2, the second member 52 is provided above the first member 51. The second member 52 may be provided above the first member 51 to provide a gap 13 s between the first member 51 and the second member 52. The second member 52 may have a substantially disc shape. As shown in FIG. 1, the second member 52 may provide a flow path 52f. The flow path 52f is provided to allow the refrigerant to flow through the second member 52. The flow path 52f receives the refrigerant supplied from a chiller unit. The chiller unit is provided outside the plasma processing chamber 10. The refrigerant flows through the flow path 52f and is returned to the chiller unit. The second member 52 may provide the above-described gas diffusion chamber 13b thereinside.

As shown in FIG. 2, the second member 52 has one or more second holes 52h. Hereinafter, the second member 52 having the plurality of second holes 52h will be described. However, the second member 52 may have a single second hole 52h. At least one of each of the plurality of first holes 51h and each of the one or more second holes 52h may be a gas hole. In the present embodiment, as an example, each of the plurality of first holes 51h and each of the one or more second holes 52h are gas holes.

The plurality of second holes 52h extend downward from the gas diffusion chamber 13b. In one embodiment, the plurality of second holes 52h extend from the gas diffusion chamber 13b toward the plurality of first holes 51h. The centerline of each of the plurality of first holes 51h and the centerline of the corresponding second hole 52h among the plurality of second holes 52h are aligned on the same straight line. The plurality of second holes 52h communicate with the plurality of first holes 51h, respectively. The plurality of second holes 52h configure a plurality of gas introduction ports 13c (see FIG. 1) together with the plurality of first holes 51h, respectively.

As shown in FIG. 2, the second member 52 includes a main body 52a and a cover layer 52b. The main body 52a is provided above the first member 51. The main body 52a may be provided above the first member 51 to face the first member 51. The main body 52a is formed of a conductor. The main body 52a may be formed of a metal such as aluminum. The cover layer 52b covers the surface of the main body 52a.

The cover layer 52b has a secondary electron emission coefficient smaller than 1. That is, the cover layer 52b is formed of a material having a secondary electron emission coefficient smaller than 1. The secondary electrons are electrons emitted from the surface of a solid when the primary electrons or the positive ions collide with the solid. The secondary electron emission coefficient is a value of the ratio of the number of secondary electrons emitted from the solid to the number of primary electrons or positive ions that collide with the solid. Therefore, the number of secondary electrons emitted from the cover layer 52b is smaller than the number of primary electrons or positive ions that collide with the cover layer 52b.

In one embodiment, the cover layer 52b may be formed of a conductor. In one embodiment, the cover layer 52b may be a layer containing diamond-like carbon (DLC), a layer containing amorphous carbon (AC), or a layer containing silicon carbide (SiC). Diamond-like carbon and amorphous carbon are conductors. The secondary electron emission coefficient of diamond-like carbon and amorphous carbon is 0.78. The secondary electron emission coefficient of the silicon carbide is smaller than 1. The cover layer 52b may be a layer containing cobalt. The secondary electron emission coefficient of cobalt is 0.97. The cover layer 52b may be a layer containing titanium. The secondary electron emission coefficient of the titanium is 0.67. The cover layer 52b may be a layer containing aluminum. The secondary electron emission coefficient of the aluminum is 0.79. The cover layer 52b may be a layer containing magnesium. The secondary electron emission coefficient of the magnesium is 0.67. The cover layer 52b may be a layer containing silicon. The secondary electron emission coefficient of the silicon is 0.73.

In another embodiment, the cover layer 52b may be formed of an insulator. The cover layer 52b may contain polyimide (PI), polytetrafluoroethylene (PTFE), or perfluoroalkoxy ethylene (PFA). The secondary electron emission coefficient of each of polyimide, polytetrafluoroethylene, and perfluoroalkoxy ethylene is smaller than 1.

The thickness of the cover layer 52b may be 0.1 µm or more and 20 µm or less. When the cover layer 52b is the layer containing diamond-like carbon, the layer containing amorphous carbon, or the layer containing silicon carbide, the thickness of the cover layer 52b may be 0.1 µm or more and 1 µm or less. When the cover layer 52b contains polyimide, polytetrafluoroethylene, or perfluoroalkoxy ethylene, the thickness of the cover layer 52b may be 10 µm or more and 20 µm or less. A method for forming the cover layer 52b is not limited. The cover layer 52b may be formed by a coating method, a Physical Vapor Deposition method (PVD), a Chemical Vapor Deposition method (CVD), thermal spraying, or the like.

In one embodiment, the second member 52 may further include an insulating layer 52c. The insulating layer 52c is provided between the cover layer 52b and the surface of the main body 52a. That is, the surface of the main body 52a is covered with the insulating layer 52c, and the insulating layer 52c is covered with the cover layer 52b. In the embodiment, the main body 52a of the second member 52 and the first member 51 are not in direct communication with each other. The insulating layer 52c may be formed of aluminum oxide (Al₂O₃). The insulating layer 52c is formed by, for example, anodizing the main body 52a. The thickness ratio between the insulating layer 52c and the cover layer 52b may be in the range of (the thickness of the insulating layer 52c):(the thickness of the cover layer 52b) = 99:1 to 50:50, in the range of 90:10 to 60:40, or in the range of 85:15 to 70:30. As an example, the thickness ratio between the insulating layer 52c and the cover layer 52b may be (the thickness of the insulating layer 52c): (the thickness of the cover layer 52b) = 8:2.

As shown in FIG. 2, the insulating layer 52c may cover at least both a region that faces the first member 51 and a region defining the plurality of second holes 52h of the entire surface of the main body 52a. The cover layer 52b covers at least a part of a region that faces the first member 51 of the entire surface of the main body 52a. In the present embodiment, as an example, the cover layer 52b covers at least the entire region that faces the first member 51 of the surface of the main body 52a.

The cover layer 52b may cover at least the region that defines the opening of each of the second holes 52h on a side of the first member 51 and faces the first member 51 of the surface of the main body 52a. When the cover layer 52b contains polyimide, polytetrafluoroethylene, or perfluoroalkoxy ethylene, the influence of heat on the cover layer 52b formed in the region is reduced.

As shown in FIG. 3, the second member 52 may include a plurality of end portions 52d. Each of the plurality of end portions 52d defines an opening of the corresponding second hole 52h on the side of the first member 51 among the plurality of second holes 52h. The surface of each of the plurality of end portions 52d is formed of the cover layer 52b. Each of the plurality of end portions 52d may have a tapered shape. That is, the openings of the plurality of second holes 52h defined by the plurality of end portions 52d each have a diameter that increases as the distance from the first member 51 decreases.

In one embodiment, the diameter of the opening of each of the plurality of second holes 52h may be larger than the diameter of each of the plurality of first holes 51h. The diameter of each of the plurality of second holes 52h may be larger than the diameter of each of the plurality of first holes 51h. Alternatively, when each of the plurality of end portions 52d has a tapered shape, the diameter of each of the openings of the plurality of second holes 52h defined by each of the plurality of end portions 52d may be larger than the diameter of each of the plurality of first holes 51h. In this case, the diameter of each of the plurality of second holes 52h may not be larger than the diameter of each of the plurality of first holes 51h in a part other than the opening defined by each of the plurality of end portions 52d.

As shown in FIG. 2, in one embodiment, the upper electrode 14 may further include a conductive member 53. The conductive member 53 is provided between the first member 51 and the second member 52. The conductive member 53 may be, for example, a spiral tube or a spring gasket formed of a conductor. When the cover layer 52b is formed of a conductor, the conductive member 53 is in contact with the first member 51 and the cover layer 52b. That is, the cover layer 52b and the first member 51 are electrically connected to each other through the conductive member 53. The conductive member 53 may be further in contact with the main body 52a of the second member 52. When the cover layer 52b is formed of an insulator, the conductive member 53 is in contact with the first member 51 and the main body 52a of the second member 52. The first member 51 and the main body 52a of the second member 52 are electrically connected to each other through the conductive member 53.

Hereinafter, the behavior of the secondary electrons in the upper electrode 14 will be described with reference to FIGS. 2 and 3. In the drawings, a circle surrounding [+] represents positive ions C. Further, a circle surrounding [-] represents electrons E. The surface of the main body 52a is covered with the cover layer 52b having a secondary electron emission coefficient smaller than 1. Therefore, even when the electrons E or the positive ions C enter the plurality of first holes 51h from the plasma processing space 10s and collide with the second member 52, the amount of electrons E (secondary electrons) emitted from the second member 52 is small. Therefore, the abnormal discharge in the upper electrode 14 is suppressed.

As described above, in one embodiment, the cover layer 52b may be formed of a conductor. The cover layer 52b may be, for example, the layer containing diamond-like carbon. According to the embodiment, the secondary electrons are exhausted from the upper electrode 14 to the ground through the cover layer 52b. The secondary electrons are exhausted to the ground through, for example, the cover layer 52b, the first member 51, and the plasma in the plasma processing space 10s. Therefore, the potential difference between the first member 51 and the second member 52 is suppressed. Therefore, the abnormal discharge in the upper electrode 14 is further suppressed.

Further, as described above, in one embodiment, the conductive member 53 may be in contact with the first member 51 and the cover layer 52b. In the embodiment, the electrons E (secondary electrons) flow to the first member 51 through the cover layer 52b and the conductive member 53 (see FIG. 2). The electrons E flowing to the first member 51 are exhausted to the ground through the plasma in the plasma processing space 10s. Therefore, the potential difference between the first member 51 and the second member 52 is suppressed. Therefore, the abnormal discharge in the upper electrode 14 is further suppressed.

Further, as described above, in one embodiment, the second member 52 may include the plurality of end portions 52d. Each of the plurality of end portions 52d may have a tapered shape. The diameter of each of the openings of the plurality of second holes 52h defined by the plurality of end portions 52d may be larger than the diameter of each of the plurality of first holes 51h. The surface of each of the end portions 52d may be formed of the cover layer 52b. The electrons E or the positive ions C entering the plurality of first holes 51h may collide with the end portion 52d of each of the plurality of second holes 52h (see FIG. 3). In the embodiment, since the surface of the end portion 52d is formed of the cover layer 52b, the emission of electrons E (secondary electrons) from the end portion 52d is effectively suppressed.

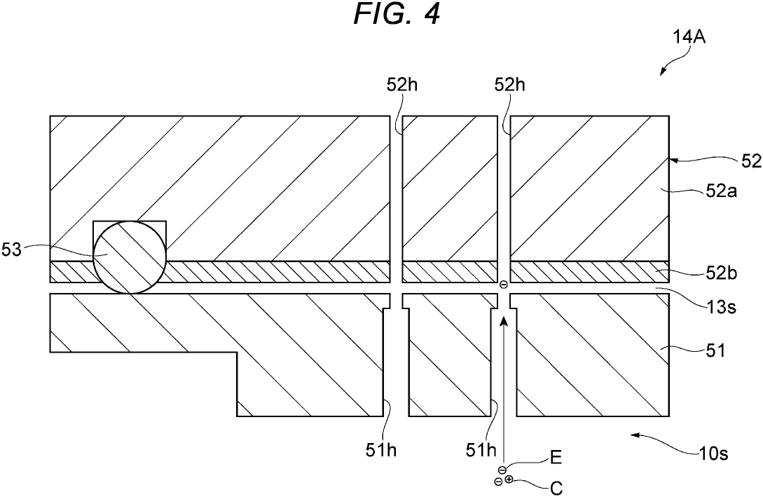

Hereinafter, the upper electrode 14A according to another exemplary embodiment will be described with reference to FIG. 4. FIG. 4 is a partially enlarged cross-sectional view of the upper electrode 14A according to another exemplary embodiment. The upper electrode 14A does not include the insulating layer 52c. In the upper electrode 14A, the cover layer 52b directly covers the surface of the main body 52a.

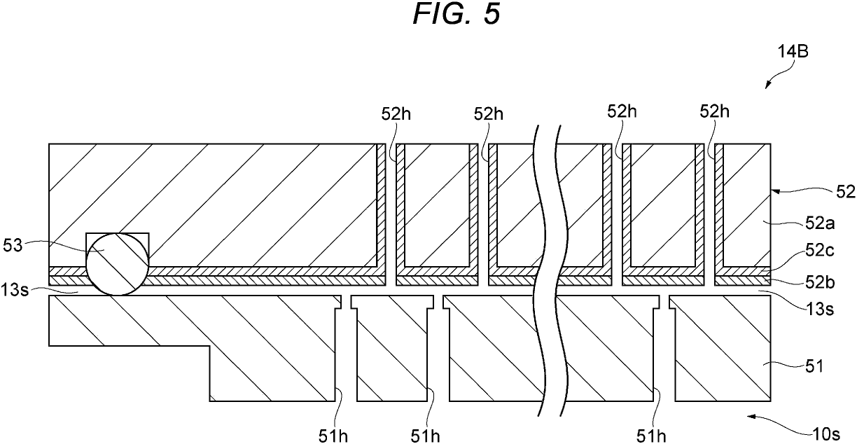

An upper electrode 14B according to still another exemplary embodiment will be described with reference to FIG. 5. FIG. 5 is a partially enlarged cross-sectional view of the upper electrode 14B according to still another exemplary embodiment. In the upper electrode 14B, the centerline of the first hole 51h and the centerline of the second hole 52h are not aligned on the same straight line. In the upper electrode 14B, the plurality of second holes 52h communicate with the plurality of first holes 51h through the gap 13s. In the exemplary embodiment shown in FIG. 5, as an example, the cover layer 52b covers at least the region that faces the opening of the first hole 51h on the side of the second member 52 of the surface of the main body 52a.

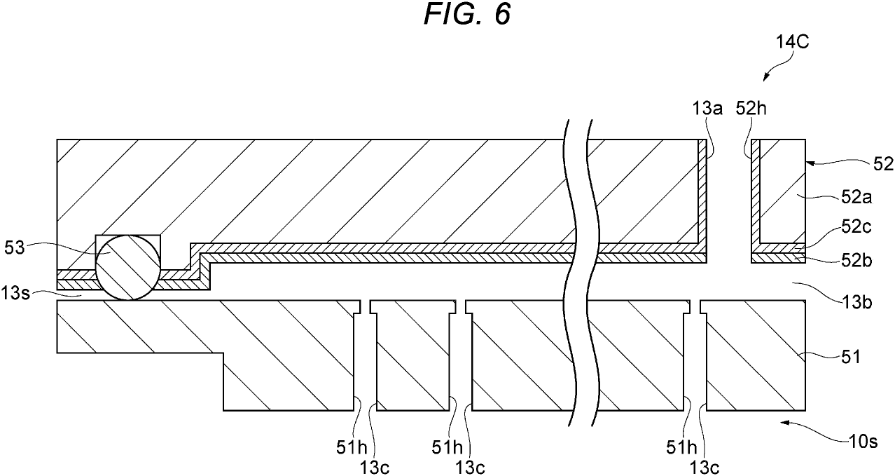

An upper electrode 14C according to still another exemplary embodiment will be described with reference to FIG. 6. FIG. 6 is a partially enlarged cross-sectional view of the upper electrode 14C according to still another exemplary embodiment. In the upper electrode 14C, the second member 52 provides a single second hole 52h. As shown in FIG. 6, in the exemplary embodiment, the gas diffusion chamber 13b is defined between the first member 51 and the second member 52. At least a part of the gap 13s configures the gas diffusion chamber 13b. The single second hole 52h configures the gas supply port 13a. The plurality of first holes 51h configure the plurality of gas introduction ports 13c.

While various exemplary embodiments have been described above, various additions, omissions, substitutions and changes may be made without being limited to the exemplary embodiments described above. Indeed, the embodiments described herein may be embodied in a variety of other forms.

Hereinafter, a test performed for the evaluation of the plasma processing apparatus 1 will be described. The present disclosure is not limited to the following test.

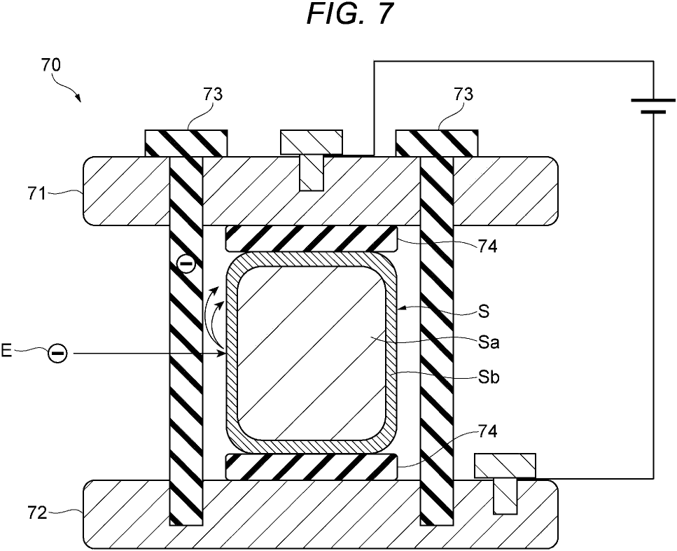

In the test, the secondary electron emission coefficient of a material used for the cover layer 52b is evaluated. FIG. 7 is a schematic cross-sectional view showing a test apparatus 70 used in the test. The test apparatus 70 includes a positive electrode 71, a negative electrode 72, insulating screws 73, and a pair of insulating plates 74. The positive electrode 71 and the negative electrode 72 sandwich a sample S through the pair of insulating plates 74. The insulating screws 73 connect the positive electrode 71 and the negative electrode 72 to each other. The sample S includes a main body Sa and a cover layer Sb. The main body Sa is a sample of aluminum covered with aluminum oxide. The cover layer Sb covers the surface of the main body Sa.

In the test, each of the following samples 1 to 5 is evaluated three each as the sample S. The cover layers Sb of the respective samples 1 to 5 are formed of different materials.

### Sample Type

Sample 1: Aluminum oxide (Al₂O₃) as the material of the cover layer Sb
Sample 2: Diamond-like carbon (DLC) as the material of the cover layer Sb
Sample 3: Polyimide (PI) as the material of the cover layer Sb
Sample 4: Polytetrafluoroethylene (PTFE) as the material of the cover layer Sb
Sample 5: Perfluoroalkoxy ethylene (PFA) as the material of the cover layer Sb

In the test, a direct-current voltage is applied to the samples 1 to 5 through the positive electrode 71 and the negative electrode 72. Then, the direct-current voltage is increased to obtain the direct-current voltage when a creeping discharge, that is, a creeping discharge start voltage (average value) occurs in each of the samples 1 to 5.

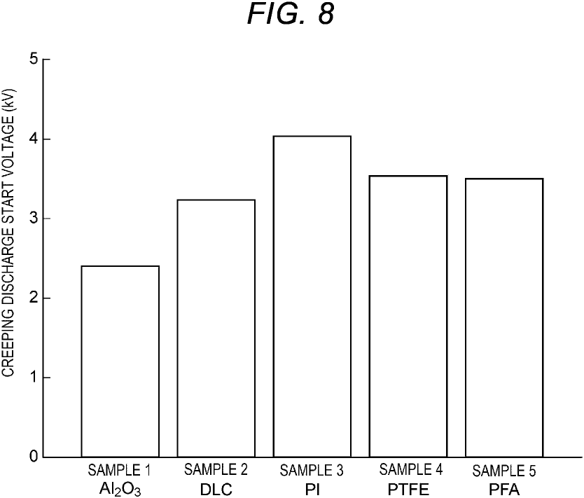

FIG. 8 is a graph illustrating test results. FIG. 8 shows the creeping discharge start voltage (average value) of each of the samples 1 to 5. The creeping discharge start voltage of the sample 1 (Al₂O₃) is 2.40 kV. The creeping discharge start voltage of the sample 2 (DLC) is 3.23 kV. The creeping discharge start voltage of the sample 3 (PI) is 4.03 kV. The creeping discharge start voltage of the sample 4 (PTFE) is 3.53 kV. The creeping discharge start voltage of the sample 5 (PFA) is 3.50 kV.

Further, the creeping discharge start voltage of the sample 2 (DLC) is 1.35 times the creeping discharge start voltage of the sample 1 (Al₂O₃) . Therefore, when the cover layer Sb is formed of a material having a secondary electron emission coefficient smaller than 1, it is confirmed that the abnormal discharge is suppressed. The creeping discharge start voltage of each of the sample 3 (PI), the sample 4 (PTFE), and the sample 5 (PFA) is larger than the creeping discharge start voltage of the sample 2 (DLC). Therefore, it is confirmed that each of the secondary electron emission coefficients of polyimide (PI), polytetrafluoroethylene (PTFE), or perfluoroalkoxy ethylene (PFA) is smaller than 1.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. An upper electrode configuring a shower head in a capacitively-coupled plasma processing apparatus, the upper electrode comprising:
a first member that includes a conductor and provides a plurality of first holes penetrating the first member; and
a second member that includes a main body including a conductor and provided above the first member and a cover layer covering at least a part of a surface of the main body, and provides one or more second holes,
wherein a secondary electron emission coefficient of the cover layer is smaller than 1.

2. The upper electrode according to claim 1,
wherein the cover layer includes a conductor.

3. The upper electrode according to claim 1,
wherein the cover layer contains polyimide, polytetrafluoroethylene, or perfluoroalkoxy ethylene.

4. An upper electrode configuring a shower head in a capacitively-coupled plasma processing apparatus, the upper electrode comprising:
a first member that includes a conductor and provides a plurality of first holes penetrating the first member; and
a second member that includes a main body including a conductor and provided above the first member and a cover layer covering at least a part of a surface of the main body, and provides one or more second holes,
wherein the cover layer is a layer containing diamondlike carbon, amorphous carbon, or silicon carbide.

5. The upper electrode according to claim 1,
wherein the second member further includes an insulating layer that is provided between the cover layer and the surface of the main body.

6. The upper electrode according to claim 4,
wherein the second member further includes an insulating layer that is provided between the cover layer and the surface of the main body.

7. The upper electrode according to claim 1, further comprising:
a conductive member that is provided between the first member and the second member,
wherein the conductive member is in contact with the first member and the cover layer.

8. The upper electrode according to claim 4, further comprising:
a conductive member that is provided between the first member and the second member,
wherein the conductive member is in contact with the first member and the cover layer.

9. The upper electrode according to claim 1,
wherein the second member provides a plurality of second holes that communicate with the plurality of first holes, respectively, as the one or more second holes.

10. The upper electrode according to claim 4,
wherein the second member provides a plurality of second holes that communicate with the plurality of first holes, respectively, as the one or more second holes.

11. The upper electrode according to claim 9,
wherein the second member includes an end portion defining an opening of each of the plurality of second holes on a side of the first member,
the end portion has a tapered shape,
a diameter of the opening of each of the plurality of second holes is larger than a diameter of each of the plurality of first holes, and
a surface of the end portion is formed of the cover layer.

12. The upper electrode according to claim 9,
wherein the second member provides a gas diffusion chamber, and
the plurality of second holes respectively extend from the gas diffusion chamber toward the plurality of first holes.

13. The upper electrode according to claim 1,
wherein the second member further provides a flow path that is provided for allowing a refrigerant to flow through the flow path.

14. The upper electrode according to claim 4,
wherein the second member further provides a flow path that is provided for allowing a refrigerant to flow through the flow path.

15. The upper electrode according to claim 1,
wherein at least one of each of the plurality of first holes and each of the one or more second holes is a gas hole.

16. The upper electrode according to claim 1,
wherein the cover layer covers at least an entire region, which faces the first member, of the surface of the main body.

17. The upper electrode according to claim 1,
wherein the cover layer covers at least a region of the surface of the main body, which region defines an opening of each of the second holes on a side of the first member and faces the first member.

18. The upper electrode according to claim 1,
wherein the cover layer covers at least a region of the surface of the main body, which region faces an opening of each of the first holes on a side of the second member.

19. A plasma processing apparatus comprising:
a plasma processing chamber that provides a processing space therewithin;
a substrate support that is provided in the plasma processing chamber; and
the upper electrode according to claim 1, the upper electrode being provided above the substrate support.

20. A plasma processing apparatus comprising:
a plasma processing chamber that provides a processing space therewithin;
a substrate support that is provided in the plasma processing chamber; and
the upper electrode according to claim 4, the upper electrode being provided above the substrate support.
